(19) United States
(12) Patent Application Publication
(10) Pub. No.: US 2025/0167010 A1
(43) Pub. Date: May 22, 2025

(54) SUBSTRATE PROCESSING APPARATUS, FLUID SUPPLY SYSTEM, AND SUBSTRATE PROCESSING METHOD

(71) Applicant: Tokyo Electron Limited, Tokyo (JP)

(72) Inventors: Mikio NAKASHIMA, Kumamoto (JP); Shota UMEZAKI, Kumamoto (JP); Takahiro HAYASHIDA, Kumamoto (JP)

(21) Appl. No.: 18/940,110

(22) Filed: Nov. 7, 2024

(30) Foreign Application Priority Data
Nov. 21, 2023 (JP) 2023-197674

(51) Int. Cl. H01L 21/67; H01L 21/02

(52) U.S. Cl. CPC H01L 21/67034; H01L 21/02101; H01L 21/6704; H01L 21/67253

(57) ABSTRACT

A substrate processing apparatus includes a processing container; and a processing fluid supply configured to supply a processing fluid in a supercritical state into the processing container. The processing fluid supply includes a fluid supply line connected to a fluid supply source and the processing container; a pump; a heater on a downstream side of the pump and configured to heat the processing fluid to generate the processing fluid in the supercritical state; a first flow rate adjuster between the pump and the heater; a first pressure measurement section between the first flow rate adjuster and the heater; a second pressure measurement section between the pump and the first flow rate adjuster; and a controller configured to control the second flow rate adjuster based on first and second pressures of the processing fluid in a liquid state measured by the first and second pressure measurement sections.

### CROSS-REFERENCE TO RELATED APPLICATIONS

This patent application is based on and claims priority to Japanese Patent Application No. 2023-197674 filed on Nov. 21, 2023, the entire contents of which are incorporated herein by reference.

### TECHNICAL FIELD

The present disclosure relates to a substrate processing apparatus, a fluid supply system, and a substrate processing method.

### BACKGROUND

A substrate processing apparatus including a processing container configured to accommodate a substrate having a surface wetted with a liquid, and a processing fluid supply configured to supply a processing fluid in a supercritical state toward the liquid is known (for example, see Patent Document 1). In the substrate processing apparatus, the processing fluid supply is controlled based on an output from a pressure sensor provided on the downstream side of the processing container.

### RELATED ART DOCUMENT

### Patent Document

[Patent Document 1] Japanese Laid-open Patent Application Publication No. 2022-101053

### SUMMARY

A substrate processing apparatus includes a processing container having a processing space configured to accommodate a substrate having a surface wetted with a liquid; and a processing fluid supply configured to supply a processing fluid in a supercritical state into the processing container. The processing fluid supply includes a fluid supply line having one end connected to a fluid supply source and another end connected to the processing container; a pump provided in the fluid supply line; a heater provided in the fluid supply line at a location on a downstream side of the pump, the heater being configured to heat the processing fluid to generate the processing fluid in the supercritical state; a first flow rate adjuster provided in the fluid supply line at a location between the pump and the heater, the first flow rate adjuster being configured to adjust a supply flow rate of the processing fluid supplied into the processing container; a first pressure measurement section provided in the fluid supply line at a location between the first flow rate adjuster and the heater, the first pressure measurement section being configured to measure a pressure of the processing fluid; a second pressure measurement section provided in the fluid supply line at a location between the pump and the first flow rate adjuster, the second pressure measurement section being configured to measure a pressure of the processing fluid; a branch point provided between the pump and the first flow rate adjuster in the fluid supply line; a connection point provided on an upstream side of the pump in the fluid supply line; a branch line connecting the branch point to the connection point; a second flow rate adjuster provided in the branch line and configured to adjust the supply flow rate of the processing fluid supplied into the processing container; and a controller configured to control the second flow rate adjuster based on a first pressure of the processing fluid in a liquid state measured by the first pressure measurement section and a second pressure of the processing fluid in the liquid state measured by the second pressure measurement section.

### BRIEF DESCRIPTION OF THE DRAWINGS

FIG. 1 is a diagram illustrating a configuration example of a substrate processing apparatus according to an embodiment;

FIG. 2 is a diagram illustrating a configuration example of a liquid processing unit;

FIG. 3 is a schematic perspective view illustrating a configuration example of a dry unit;

FIG. 4 is a diagram illustrating a configuration example of the dry unit;

FIG. 5 is a diagram illustrating a configuration example of a supply unit;

FIG. 6 is a diagram illustrating a configuration example of a third flow rate adjuster and its surroundings;

FIG. 7 is a diagram (1) illustrating a substrate processing method according to the embodiment;

FIG. 8 is a diagram (2) illustrating the substrate processing method according to the embodiment;

FIG. 9 is a diagram (3) illustrating the substrate processing method according to the embodiment;

FIG. 10 is a diagram (4) illustrating the substrate processing method according to the embodiment;

FIG. 11 is a diagram (5) illustrating the substrate processing method according to the embodiment;

FIG. 12 is a diagram (6) illustrating the substrate processing method according to the embodiment;

FIG. 13 is a diagram (7) illustrating the substrate processing method according to the embodiment; and

FIG. 14 is a diagram (8) illustrating the substrate processing method according to the embodiment.

### DETAILED DESCRIPTION

According to the present disclosure, the responsiveness of the flow rate control of the supercritical fluid can be improved.

Non-limiting exemplary embodiments of the present disclosure will be described below with reference to the accompanying drawings. In all the accompanying drawings, the same or corresponding members or parts are denoted by the same or corresponding reference symbols, and a duplicated description will be omitted.

### [Configuration of Substrate Processing Apparatus]

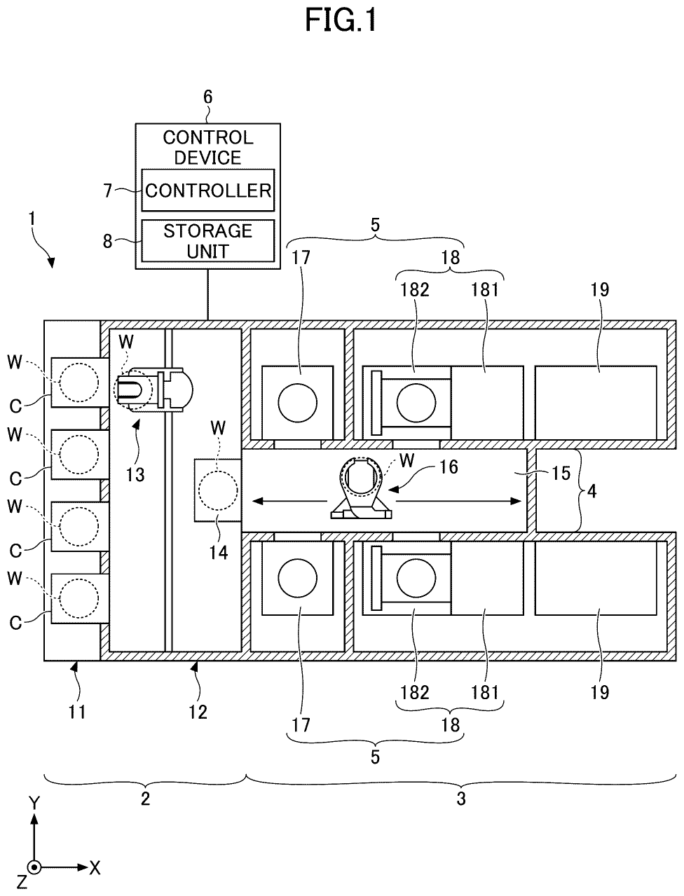

A configuration of a substrate processing apparatus 1 according to an embodiment will be described with reference to FIG. 1. FIG. 1 is a diagram illustrating a configuration example of the substrate processing apparatus 1 according to the embodiment. In the following description, in order to clarify the positional relationship, the X axis, the Y axis, and the Z axis orthogonal to each other are defined, and the Z axis positive side is in a vertically upward direction.

As illustrated in FIG. 1, the substrate processing apparatus 1 includes a carry-in/out station 2, a processing station 3, and a control device 6. The carry-in/out station 2 and the processing station 3 are provided adjacent to each other.

The carry-in/out station 2 includes a carrier mounting section 11 and a transfer section 12. A carrier C is mounted on the carrier mounting section 11. The carrier C accommodates multiple substrates in a horizontal state. The substrate is, for example, a semiconductor wafer (hereinafter referred to as a “wafer W”).

The transfer section 12 is provided adjacent to the carrier mounting section 11. A transfer device 13 and a delivery section 14 are disposed inside the transfer section 12.

The transfer device 13 includes a wafer holding mechanism for holding the wafer W. The transfer device 13 can move in the horizontal direction, move in the vertical direction, and turn around the vertical axis. The transfer device 13 transfers the wafer W between the carrier C and the delivery section 14 by using the wafer holding mechanism.

The processing station 3 is provided adjacent to the transfer section 12. The processing station 3 includes a transfer block 4, multiple processing blocks 5, and multiple supply units 19.

The transfer block 4 includes a transfer area 15 and a transfer device 16. The transfer area 15 is, for example, a cuboid region extending along the arrangement direction (the X-axis direction) of the carry-in/out station 2 and the processing station 3. The transfer device 16 is disposed in the transfer area 15.

The transfer device 16 includes a wafer holding mechanism for holding the wafer W. The transfer device 16 can move in the horizontal direction, move in the vertical direction, and turn around the vertical axis. The transfer device 16 transfers the wafer W between the delivery section 14 and the multiple processing blocks 5 by using the wafer holding mechanism.

The multiple processing blocks 5 are arranged adjacent to the transfer area 15 on both sides of the transfer area 15. Specifically, the multiple processing blocks 5 are disposed on one side (the Y-axis positive side) and the other side (the Y-axis negative side) of the transfer area 15 in a direction (the Y-axis direction) orthogonal to the arrangement direction (the X-axis direction) of the carry-in/out station 2 and the processing station 3.

Although not illustrated, the multiple processing blocks 5 are arranged in multiple stages (for example, three stages) along the vertical direction. The transfer of the wafer W between the processing block 5 and the delivery section 14 disposed at each stage is performed by one transfer device 16 disposed in the transfer block 4. The number of stages of the multiple processing blocks 5 is not limited to three.

Each processing block 5 includes a liquid processing unit 17 and a dry unit 18.

The liquid processing unit 17 performs a cleaning process for cleaning the upper surface of the wafer W, where a pattern is formed. The liquid processing unit 17 performs a liquid film formation process of forming a liquid film on the upper surface of the wafer W after the cleaning process. A configuration of the liquid processing unit 17 will be described later.

The dry unit 18 performs a supercritical drying process on the wafer W after the liquid film formation process. Specifically, the dry unit 18 brings the wafer W after the liquid film formation process into contact with a processing fluid in a supercritical state (hereinafter, also referred to as a “supercritical fluid”) to dry the wafer W. A configuration of the dry unit 18 will be described later.

The liquid processing unit 17 and the dry unit 18 are arranged along the transfer area 15 (along the X-axis direction). The liquid processing unit 17 is disposed closer to the carry-in/out station 2 than the dry unit 18 is.

Each of the processing blocks 5 includes one liquid processing unit 17 and one dry unit 18. The substrate processing apparatus 1 is provided with an equal number of liquid processing units 17 and dry units 18.

The dry unit 18 includes a processing area 181 and a delivery area 182. In the processing area 181, the supercritical drying process is performed. In the delivery area 182, the wafer W is delivered between the transfer block 4 and the processing area 181. The processing area 181 and the delivery area 182 are arranged along the transfer area 15.

The delivery area 182 is disposed closer to the liquid processing unit 17 than the processing area 181 is. In each of the processing blocks 5, the liquid processing unit 17, the delivery area 182, and the processing area 181 are arranged in this order along the transfer area 15.

One supply unit 19 is disposed for three processing blocks 5. For example, one supply unit 19 is disposed for three processing blocks 5 stacked in the vertical direction.

The supply unit 19 supplies the processing fluid to the dry unit 18. Specifically, the supply unit 19 includes a supply device group including a flow meter, a flow rate regulator, a back pressure valve, a heater, and the like, and a housing that houses the supply device group. In the present embodiment, the supply unit 19 supplies carbon dioxide (CO₂) as the processing fluid to the dry unit 18. A configuration of the supply unit 19 will be described later. The processing fluid can be supplied from one supply unit 19 to three processing blocks 5.

The control device 6 is, for example, a computer, and includes a controller 7 and a storage unit 8. The controller 7 includes a microcomputer including a central processing unit (CPU), a read only memory (ROM), a random access memory (RAM), an input/output port, and the like, and various circuits. The CPU of the microcomputer reads and executes the program stored in the ROM to achieve the control of the transfer devices 13 and 16, the liquid processing unit 17, the dry unit 18, the supply unit 19, and the like.

The program may be stored in a computer-readable storage medium and installed from the storage medium to the storage unit 8 of the control device 6. Examples of the computer-readable storage medium include a hard disk (HD), a flexible disk (FD), a compact disc (CD), a magneto-optical disk (MO), a memory card, and the like.

The storage unit 8 is implemented by, for example, a semiconductor memory element, such as a RAM or a flash memory, or a storage device, such as a hard disk or an optical disk.

In the substrate processing apparatus 1 configured as described above, first, the transfer device 13 of the carry-in/out station 2 takes out the wafer W from the carrier C mounted on the carrier mounting section 11, and mounts the taken wafer W on the delivery section 14. The wafer W mounted on the delivery section 14 is taken out from the delivery section 14 by the transfer device 16 of the processing station 3 and is carried into the liquid processing unit 17.

The wafer W carried into the liquid processing unit 17 undergoes the cleaning process and the liquid film formation process by the liquid processing unit 17, and then carried out from the liquid processing unit 17 by the transfer device 16. The wafer W carried out from the liquid processing unit 17 is carried into the dry unit 18 by the transfer device 16, and undergoes the drying process by the dry unit 18.

The wafer W that undergoes the drying process by the dry unit 18 is carried out from the dry unit 18 by the transfer device 16 and is mounted on the delivery section 14. The processed wafer W mounted on the delivery section 14 is returned to the carrier C of the carrier mounting section 11 by the transfer device 13.

### [Configuration of Liquid Processing Unit]

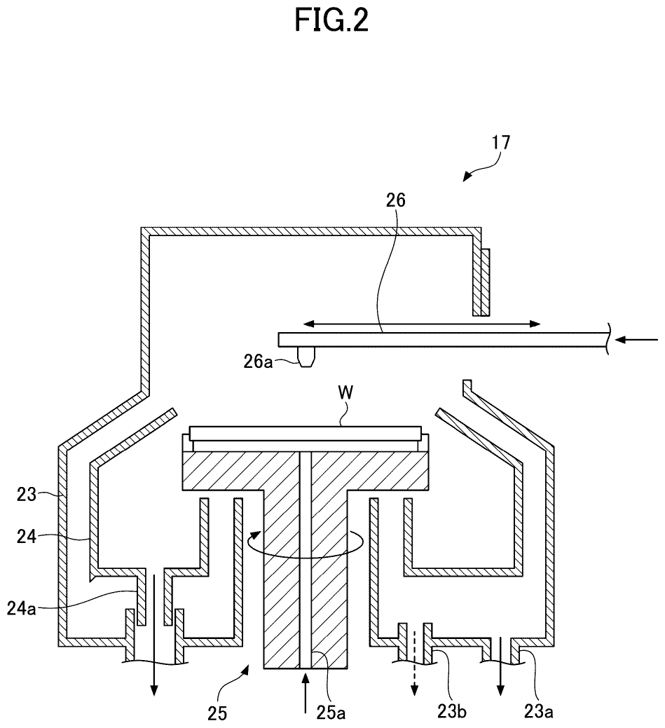

The configuration of the liquid processing unit 17 will be described with reference to FIG. 2. FIG. 2 is a diagram illustrating a configuration example of the liquid processing unit 17. The liquid processing unit 17 is configured as a single-wafer cleaning device that cleans the wafers W one by one by, for example, spin cleaning.

As illustrated in FIG. 2, the liquid processing unit 17 holds the wafer W substantially horizontally by a wafer holding mechanism 25 disposed in an outer chamber 23 forming a processing space, and rotates wafer W by rotating the wafer holding mechanism 25 around the vertical axis.

The liquid processing unit 17 positions a nozzle arm 26 above the rotating wafer W and supplies a chemical liquid and a rinse liquid in a predetermined order from a chemical liquid nozzle 26a provided at a tip of the nozzle arm 26 to perform the cleaning process on the upper surface of the wafer W.

In the liquid processing unit 17, a chemical liquid supply path 25a is also formed inside the wafer holding mechanism 25. The lower surface of the wafer W is also cleaned by a chemical liquid and a rinse liquid supplied from the chemical liquid supply path 25a.

In the cleaning process, for example, particles and organic contaminants are first removed by an SC1 solution (a mixed solution of ammonia and a hydrogen-peroxide solution), which is an alkaline chemical solution. Next, rinse cleaning is performed using deionized water (hereinafter, referred to as “DIW”), which is a rinse liquid.

Next, a natural oxide film is removed by a diluted hydrofluoric acid (hereinafter, referred to as “DHF”) solution, which is an acidic chemical solution, and then rinse cleaning is performed by DIW.

The above-described various chemical liquids are received by the outer chamber 23 and an inner cup 24 disposed in the outer chamber 23, and are drained from a liquid drain port 23a provided at the bottom of the outer chamber 23 and a liquid drain port 24a provided at the bottom of the inner cup 24. The atmosphere inside the outer chamber 23 is evacuated through an exhaust port 23b provided at the bottom of the outer chamber 23.

The liquid film formation process is performed after the rinse process in the cleaning process. Specifically, the liquid processing unit 17 supplies isopropyl alcohol (IPA) in a liquid state (hereinafter, also referred to as an “IPA liquid”) to the upper surface and the lower surface of wafer W while rotating the wafer holding mechanism 25. With this, the DIW remaining on both surfaces of the wafer W is replaced with the IPA. Subsequently, the liquid processing unit 17 gently stops the rotation of the wafer holding mechanism 25.

The wafer W after the liquid film formation process has been performed is delivered to the transfer device 16 by a delivery mechanism, which is not illustrated, provided in the wafer holding mechanism 25, in a state where the liquid film of the IPA liquid is formed on the upper surface of the wafer W (the surface of the wafer W is wetted with the IPA liquid), and is carried out from the liquid processing unit 17.

The liquid film formed on the wafer W prevents the pattern collapse from occurring due to the evaporation (vaporization) of the liquid on the upper surface of the wafer W during the transfer of the wafer W from the liquid processing unit 17 to the dry unit 18 or when the wafer W is carried into the dry unit 18.

### [Configuration of Dry Unit]

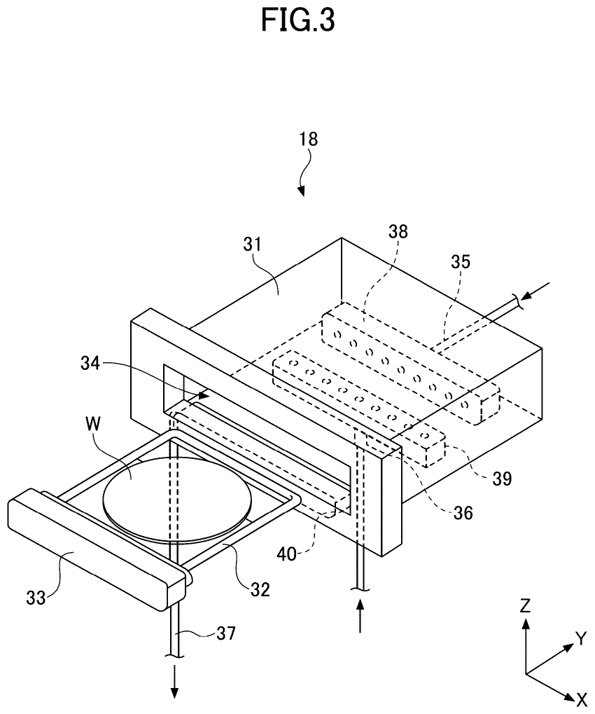

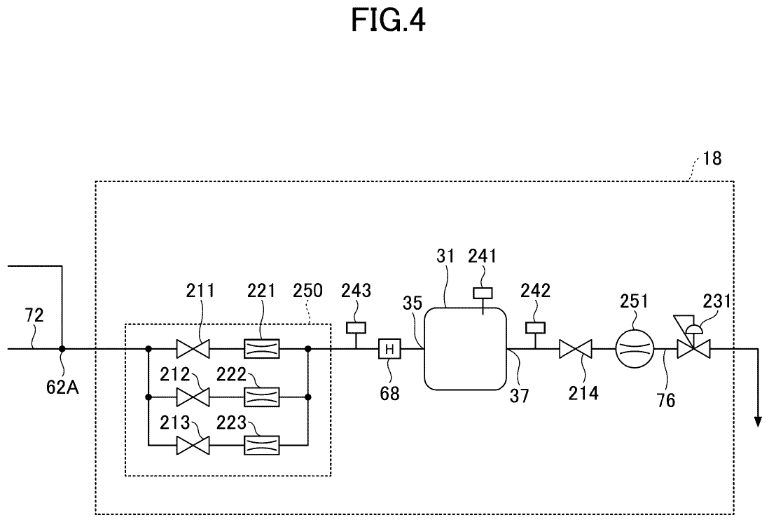

The configuration of the dry unit 18 will be described with reference to FIG. 3 and FIG. 4. FIG. 3 is a schematic perspective view illustrating a configuration example of the dry unit 18. FIG. 4 is a diagram illustrating the configuration example of the dry unit 18.

As illustrated in FIG. 3, the dry unit 18 includes a main body 31, a holding plate 32, and a cover member 33. An opening 34 for carrying in and out the wafer W is formed in the housing-shaped main body 31. The holding plate 32 holds the wafer W to be processed in the horizontal direction. The cover member 33 supports the holding plate 32. The cover member 33 seals the opening 34 when the wafer W is carried into the main body 31. The main body 31 is an example of a processing container.

The main body 31 is a container, in which a processing space in which a wafer W having, for example, a 300 mm radius can be accommodated, is formed inside. Supply ports 35 and 36 and a drain port 37 are provided in walls of the main body 31. The supply ports 35 and 36 and the drain port 37 are connected to supply flow paths and an exhaust flow path for circulating the supercritical fluid in the dry unit 18.

The supply port 35 is connected to a side surface of the housing-shaped main body 31 on the opposite side of the opening 34. The supply port 36 is connected to a bottom surface of the main body 31. The drain port 37 is connected on the lower side of the opening 34. Although two supply ports 35 and 36 and one drain port 37 are illustrated in FIG. 3, the number of supply ports 35 and 36 and the drain port 37 is not particularly limited.

Inside the main body 31, fluid supply headers 38 and 39 and a fluid drain header 40 are provided. In the fluid supply headers 38 and 39, multiple supply ports are formed in line in the longitudinal direction of the fluid supply headers 38 and 39. In the fluid drain header 40, multiple drain ports are formed in line in the longitudinal direction of the fluid drain header 40.

The fluid supply header 38 is connected to the supply port 35. The fluid supply header 38 is provided adjacent to the side surface on the opposite side of the opening 34 inside the housing-shaped main body 31. The multiple supply ports formed in line in the fluid supply header 38 is directed toward the opening 34.

The fluid supply header 39 is connected to the supply port 36. The fluid supply header 39 is provided at the center of the bottom surface inside the housing-shaped main body 31. The multiple supply ports formed in line in the fluid supply header 39 are directed upward.

The fluid drain header 40 is connected to the drain port 37. The fluid drain header 40 is provided adjacent to a side surface on the opening 34 side inside the housing-shaped main body 31 below the opening 34. The multiple drain ports formed in line in the fluid drain header 40 are directed upward.

The fluid supply headers 38 and 39 supply the supercritical fluid into the main body 31. The fluid drain header 40 guides the supercritical fluid in the main body 31 to the outside of the main body 31 and drains the supercritical fluid. The supercritical fluid drained to the outside of the main body 31 through the fluid drain header 40 includes the IPA liquid dissolved from the surface of the wafer W into the supercritical fluid in the supercritical state.

As illustrated in FIG. 4, a second supply line 72 of the supply unit 19 is connected to the dry unit 18. The second supply line 72 is branched into two supply lines (omitted in FIG. 4) in the dry unit 18, one is connected to the supply port 35, and the other is connected to the supply port 36 (omitted in FIG. 4). A first flow rate adjuster 250, a pressure sensor 243, and a heater 68 are provided in the second supply line 72 in this order from the upstream side (the supply unit 19 side).

The first flow rate adjuster 250 adjusts the supply flow rate of the processing fluid supplied into the main body 31. The first flow rate adjuster 250 includes valves 211 to 213 and orifices 221 to 223.

The valves 211, 212, and 213 are connected in parallel to each other. The valves 211, 212, and 213 are valves for adjusting on and off of the flow of the processing fluid. The valves 211, 212, and 213 allow the process fluid to flow through the orifices 221, 222, and 223, respectively, in an open state, and do not allow the process fluid to flow through the orifices 221, 222, and 223, respectively, in a closed state. The valves 211, 212, and 213 are examples of a first open/close valve.

The orifices 221, 222 and 223 are connected in series with the valves 211, 212 and 213, respectively. The orifices 221, 222, and 223 serve to reduce the flow rate of the processing fluid in a gas state or a liquid state supplied from the supply unit 19 through the valves 211, 212, and 213, respectively, and to adjust the pressure. The orifices 221, 222, and 223 can cause the processing fluid whose pressure is adjusted to circulate through the second supply line 72 on the downstream side. The orifices 221, 222, and 223 are examples of a first throttle.

The pressure sensor 243 measures the pressure of the processing fluid flowing through the second supply line 72 between the first flow rate adjuster 250 and the heater 68. That is, the pressure sensor 243 can measure the pressure on the secondary side of the orifices 221, 222, and 223. The output of the pressure sensor 243 is transmitted to the controller 7. The pressure sensor 243 is an example of a first pressure measurement section.

The heater 68 is, for example, a spiral heater. The heater 68 is wound around the second supply line 72 and heats the processing fluid in the gas state or the liquid state flowing through the second supply line 72 to generate the processing fluid in the supercritical state. The heater 68 is an example of a heater.

A drain line 76 is connected to the drain port 37. The drain line 76 is provided with a pressure sensor 242, a valve 214, a flow meter 251, and a back pressure valve 231 in this order from the upstream side, that is, the main body 31 side. The drain line 76, the pressure sensor 242, the valve 214, the flow meter 251, and the back pressure valve 231 constitute a part of a drain section.

The pressure sensor 242 measures the pressure of the processing fluid flowing through the drain line 76 immediately after the main body 31. That is, the pressure sensor 242 can measure the pressure of the processing fluid in the main body 31. The output of the pressure sensor 242 is transmitted to the controller 7. The pressure sensor 242 is an example of a third pressure measurement section.

The valve 214 is a valve for adjusting on and off of the flow of the processing fluid, and allows the processing fluid to flow through the drain line 76 on the downstream side in an open state and does not allow the processing fluid to flow through the drain line 76 on the downstream side in a closed state.

The flow meter 251 measures the drain flow rate of the processing fluid flowing through the drain line 76. The output of the flow meter 251 is transmitted to the controller 7.

When the pressure on the primary side of the drain line 76 exceeds a set pressure, the valve opening degree of the back pressure valve 231 is adjusted to allow the fluid to flow to the secondary side, thereby maintaining the pressure on the primary side at the set pressure. For example, the set pressure of the back pressure valve 231 is adjusted by the controller 7 based on the output of the pressure sensor 242. The back pressure valve 231 is an example of a pressure adjuster.

A temperature sensor 241 configured to detect the temperature of the processing fluid in the main body 31 is provided. The output of the temperature sensor 241 is transmitted to the controller 7.

In the dry unit 18, the IPA liquid in the pattern formed on the wafer W is gradually dissolved in the supercritical fluid by being brought into contact with the supercritical fluid in a high-pressure state (for example, 16 MPa), and the IPA liquid in the pattern is gradually replaced with the supercritical fluid. Ultimately, the space in the pattern is filled with only the supercritical fluid.

After the IPA liquid is removed from the pattern, CO₂ changes from a supercritical state to a gas state by reducing the pressure inside the main body 31 from a high-pressure state to the atmosphere, and the space in the pattern is occupied only by the gas. In such a way, the IPA liquid in the pattern is removed, and the drying process of the wafer W is completed.

The supercritical fluid has a lower viscosity than a liquid (for example, the IPA liquid), has a high ability to dissolve a liquid, and has no interface with a liquid or a gas in equilibrium with the supercritical fluid. This allows the drying process using the supercritical fluid to dry the liquid without being affected by the surface tension. Therefore, according to the embodiment, the pattern can be prevented from falling down during the drying process.

In the embodiment, the example in which the IPA liquid is used as the dry prevention liquid and CO₂ in the supercritical state is used as the processing fluid is described, but a liquid other than the IPA liquid may be used as the dry prevention liquid, and a fluid other than CO₂ in the supercritical state may be used as the processing fluid.

### [Configuration of Supply Unit]

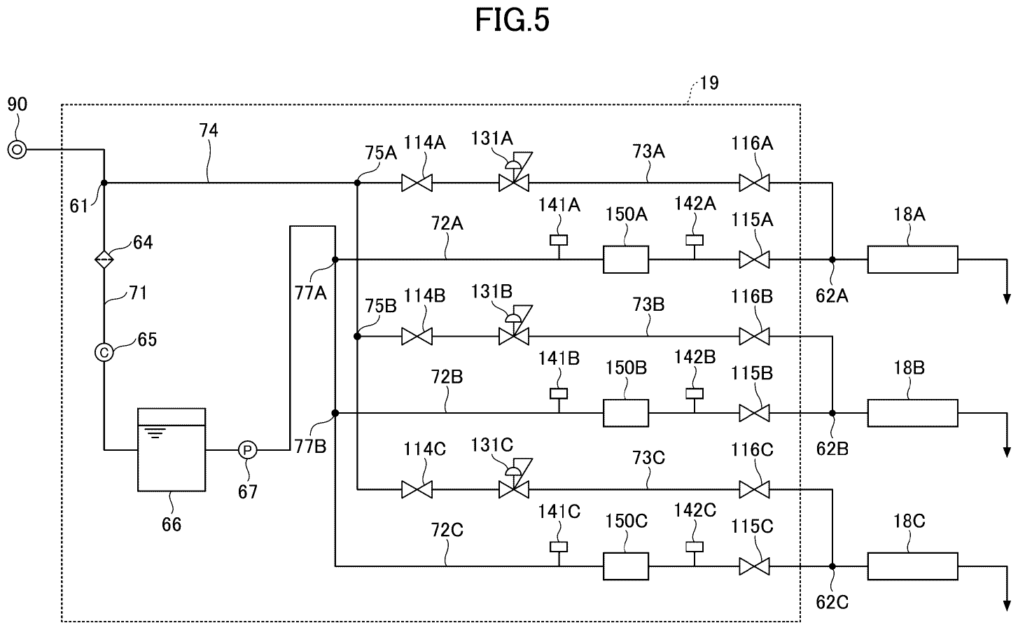

The configuration of the supply unit 19 will be described with reference to FIG. 5. FIG. 5 is a diagram illustrating a configuration example of the supply unit 19. The supply unit 19 illustrated in FIG. 5 supplies the processing fluid to the three dry units 18A, 18B and 18C. The dry units 18A to 18C correspond to the dry unit 18 in FIG. 4.

The supply unit 19 includes a first supply line 71 connected to a processing fluid supply source 90 and multiple second supply lines 72A, 72B and 72C connected to the first supply line 71. The second supply lines 72A, 72B, and 72C are connected to the first supply line 71 at multiple branch points 77A and 77B provided in the first supply line 71. Specifically, the second supply line 72A is connected to the first supply line 71 at the branch point 77A, and the second supply lines 72B and 72C are connected to the first supply line 71 at the branch point 77B. The second supply lines 72A to 72C correspond to the second supply line 72 in FIG. 4. The second supply line 72A is connected to the dry unit 18A, the second supply line 72B is connected to the dry unit 18B, and the second supply line 72C is connected to the dry unit 18C. The processing fluid supply source 90 is an example of a fluid supply source, and the first supply line 71 and the second supply lines 72A to 72C constitute a part of a fluid supply line.

A connection point 61 is provided on the first supply line 71. In the first supply line 71, a filter 64, a condenser 65, a tank 66, and a pump 67 are provided in this order from the upstream side (the processing fluid supply source 90 side). The connection point 61 is provided on the upstream side of the filter 64.

The filter 64 filters the processing fluid in the gas state flowing in the first supply line 71 to remove foreign substances contained in the processing fluid. By removing the foreign substances in the processing fluid by the filter 64, the generation of particles on the surface of the wafer W can be suppressed during the drying process of the wafer W using the supercritical fluid.

The condenser 65 is connected to, for example, a cooling water supply unit, which is not illustrated, and can exchange heat between the cooling water and the processing fluid in the gas state. With this, the condenser 65 cools the processing fluid in the gas state flowing through the first supply line 71 to generate the processing fluid in the liquid state. The condenser 65 is an example of a cooler.

The tank 66 stores the processing fluid in the liquid state generated by the condenser 65. The pump 67 supplies the processing fluid in the liquid state stored in the tank 66 to the downstream side of the first supply line 71.

A branch point 62A is provided on the second supply line 72A, a branch point 62B is provided on the second supply line 72B, and a branch point 62C is provided on the second supply line 72C. The branch point 62A is provided between a valve 115A and the dry unit 18A, the branch point 62B is provided between a valve 115B and the dry unit 18B, and the branch point 62C is provided between a valve 115C and the dry unit 18C. The supply unit 19 includes a first branch line 73A connected to the branch point 62A, a first branch line 73B connected to the branch point 62B, and a first branch line 73C connected to the branch point 62C.

In the first branch line 73A, a valve 116A, a back pressure valve 131A, and a valve 114A are provided in this order from the upstream side (the branch point 62A side). In the first branch line 73B, a valve 116B, a back pressure valve 131B, and a valve 114B are provided in this order from the upstream side (the branch point 62B side). In the first branch line 73C, a valve 116C, a back pressure valve 131C, and a valve 114C are provided in this order from the upstream side (the branch point 62C side).

The valve 116A is a valve for adjusting on and off of the flow of the processing fluid, allows the processing fluid to flow through the first branch line 73A on the downstream side in an open state, and does not allow the processing fluid to flow through the first branch line 73A on the downstream side in a closed state. The valves 116B and 116C have substantially the same configuration as the valve 116A.

When the pressure on the primary side of the first branch line 73A exceeds a set pressure, the valve opening degree of the back pressure valve 131A is adjusted to allow the fluid to flow to the secondary side, thereby maintaining the pressure on the primary side at the set pressure. For example, the set pressure of the back pressure valve 131A is adjusted by the controller 7 based on the outputs of the pressure sensor 142A and the pressure sensor 243. The back pressure valves 131B and 131C have substantially the same configuration as the back pressure valve 131A. The back pressure valves 131A to 131C are examples of a second flow rate adjuster.

The valve 114A is a valve for adjusting on and off of the flow of the processing fluid, and allows the processing fluid to flow through the first branch line 73A on the downstream side in an open state, and does not allow the processing fluid to flow through the first branch line 73A on the downstream side in a closed state. The valves 114B and 114C have substantially the same configuration as the valve 114A.

The supply unit 19 includes a second branch line 74 connected to the first branch lines 73A to 73C. The first branch lines 73A to 73C are connected to the second branch line 74 at multiple connection points 75A and 75B provided in the second branch line 74. Specifically, the first branch line 73A is connected to the second branch line 74 at the connection point 75A, and the first branch lines 73B and 73C are connected to the second branch line 74 at the connection point 75B. The second branch line 74 is connected to the connection point 61. That is, the second branch line 74 connects the first branch lines 73A to 73C to the connection point 61. Here, the first branch lines 73A to 73C may be directly connected to the first supply line 71 on the upstream side of the filter 64 at independent connection points, instead of providing the second branch line 74 in the configuration.

In the second supply line 72A, a pressure sensor 141A, a third flow rate adjuster 150A, a pressure sensor 142A, and a valve 115A are provided in this order from the upstream side (the branch point 77A side) between the branch point 77A and the branch point 62A. In the second supply line 72B, a pressure sensor 141B, a third flow rate adjuster 150B, a pressure sensor 142B, and a valve 115B are provided in this order from the upstream side (the branch point 77B side) between the branch point 77B and the branch point 62B. In the second supply line 72C, a pressure sensor 141C, a third flow rate adjuster 150C, a pressure sensor 142C, and a valve 115C are provided in this order from the upstream side (the branch point 77B side) between the branch point 77B and the branch point 62C.

The pressure sensor 141A measures the pressure of the processing fluid flowing through the second supply line 72A on the upstream side of the third flow rate adjuster 150A. The output of the pressure sensor 141A is transmitted to the controller 7. The pressure sensors 141B and 141C have substantially the same configuration as the pressure sensor 141A.

The third flow rate adjuster 150A adjusts the flow rate of the processing fluid flowing through the first branch line 73A. The third flow rate adjusters 150B and 150C have substantially the same configuration as the third flow rate adjuster 150A.

The pressure sensor 142A measures the pressures of the processing fluid flowing through the second supply line 72A between the third flow rate adjuster 150A and the valve 115A. That is, the pressure sensor 142A can measure the pressures on the primary sides of the orifices 221, 222, and 223. The pressure sensors 142B and 142C have substantially the same configuration as the pressure sensor 142A. The pressures sensors 142A to 142C are examples of a second pressure measurement section.

The valve 115A is a valve for adjusting on and off of the flow of the processing fluid, allows the processing fluid to flow through the second supply line 72A on the downstream side in an open state, and does not allow the processing fluid to flow through the second supply line 72A on the downstream side in a closed state. The valves 115B and 115C have substantially the same configuration as the valve 115A.

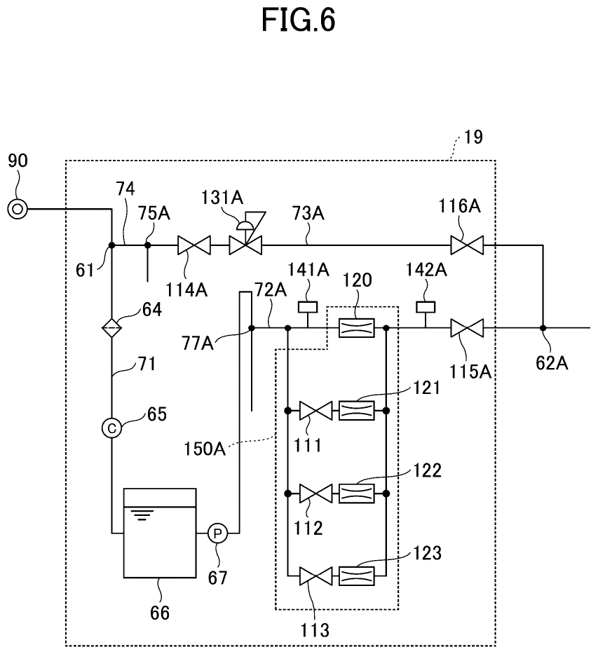

A configuration of the third flow rate adjuster 150A will be described with reference to FIG. 6. FIG. 6 is a diagram illustrating a configuration example of the third flow rate adjuster 150A and its surroundings. The third flow rate adjusters 150B and 150C have substantially the same configuration as the third flow rate adjuster 150A.

As illustrated in FIG. 6, the third flow rate adjuster 150A includes orifices 120 to 123 and valves 111 to 113. The orifices 121, 122 and 123 are connected in parallel to the orifice 120. The valve 111 is connected in series with the orifice 121. The valve 112 is connected in series with the orifice 122. The valve 113 is connected in series with the orifice 123.

The orifices 120 to 123 serve to reduce the flow rate of the processing fluid flowing through the second supply line 72A and to adjust the pressure. The orifices 120 to 123 can cause the processing fluid whose pressure has been adjusted to circulate through the second supply line 72A on the downstream side.

The valves 111 to 113 are valves for adjusting on and off of the flow of the processing fluid, allow the processing fluid to flow through the second supply line 72A on the downstream side in an open state, and do not allow the processing fluid to flow through the second supply line 72A on the downstream side in a closed state.

A basic operation of the supply unit 19 will be described. The processing fluid in the gas state supplied from the processing fluid supply source 90 to the first supply line 71 is supplied to the condenser 65 via the filter 64 and is cooled and condenses by the condenser 65. The condensed processing fluid is stored in the tank 66. The processing fluid in the liquid state stored in the tank 66 is converted into a high-pressure fluid by the pump 67, and a portion of the high-pressure fluid is supplied to the dry units 18A to 18C. The high-pressure fluid supplied to the dry units 18A to 18C is brought into a supercritical state by the heater 68 and is used for drying. The other portion of the high-pressure fluid flows through the first branch lines 73A to 73C and returns to the first supply line 71 from the connection point 61. In such a way, the processing fluid circulates in the supply unit 19.

### [Substrate Processing Method]

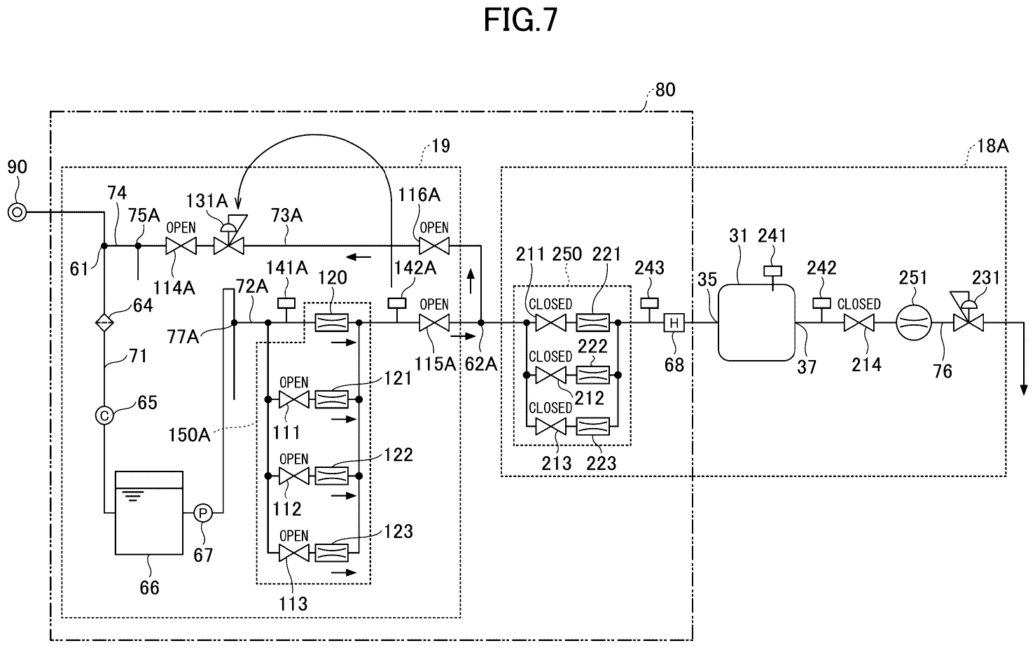

A substrate processing method according to the embodiment will be described with reference to FIG. 7 to FIG. 14. In the following, a drying method (the substrate processing method) performed using the dry unit 18A will be described. FIG. 7 to FIG. 14 are diagrams illustrating the substrate processing method according to the embodiment. FIG. 7 to FIG. 14 illustrate, for example, a specific operation of the supply unit 19 when the processing fluid is supplied to the dry unit 18A. During the operation illustrated in FIG. 7 to FIG. 14, the pump 67 continues to operate. As illustrated in FIG. 7 to FIG. 14, a processing fluid supply 80 includes the supply unit 19; and the first flow rate adjuster 250, the pressure sensor 243, and the heater 68 in the dry unit 18A. The processing fluid supply 80 may include the control device 6. The processing fluid supply 80 is an example of a fluid supply system.

### <Wait Process>

A wait process is a process of waiting for the supply of the processing fluid after the wafer W is transferred to the dry unit 18A. In the wait process, as illustrated in FIG. 7, the valves 111 to 113 are opened. Additionally, the valves 114A, 115A, and 116A are opened, and the valves 211 to 214 are closed. The processing fluid guided to the second supply line 72A reaches the branch point 62A via the orifice 120 and the orifices 121 to 123, and flows into the first branch line 73A. The processing fluid guided to the first branch line 73A reaches the connection point 61 via the valves 116A, the back pressure valves 131A, the valve 114A, and the second branch line 74, and thereafter returns to the tank 66 via the filter 64 and the condenser 65.

During this series of operations, the controller 7 receives the output from the pressure sensor 142A and adjusts the set pressure of the back pressure valve 131A so that the pressure of the processing fluid flowing through a portion on the downstream side of the orifice 120 of the second supply line 72A is at a preset pressure (e.g., 19.0 MPa). That is, the controller 7 controls the pressures of the processing fluids at the branch point 62A by changing the amount of the processing fluid flowing through the first branch line 73A.

In the wait process, the processing fluid is not supplied from the processing fluid supply source 90, and the processing fluid circulates in the supply unit 19. At this time, the valves 111 to 113 are open, and thus the processing fluid is less likely to stagnate in the third flow rate adjuster 150A. Therefore, the generation of particles due to the stagnation can be suppressed.

### <Pressurization Process>

A pressurization process is performed after the wait process. The pressurization process is a process of increasing the pressure in the main body 31 to a processing pressure. In the pressurization process, first, the pressure is increased by supplying the processing fluid in the supercritical state into the main body 31 at a first flow rate. Subsequently, the pressure is further increased by supplying the processing fluid in the supercritical state into the main body 31 at a second flow rate greater than the first flow rate. Subsequently, the pressure is further increased by supplying the processing fluid in the supercritical state into the main body 31 at a third flow rate greater than the second flow rate. That is, the pressure is increased in three stages.

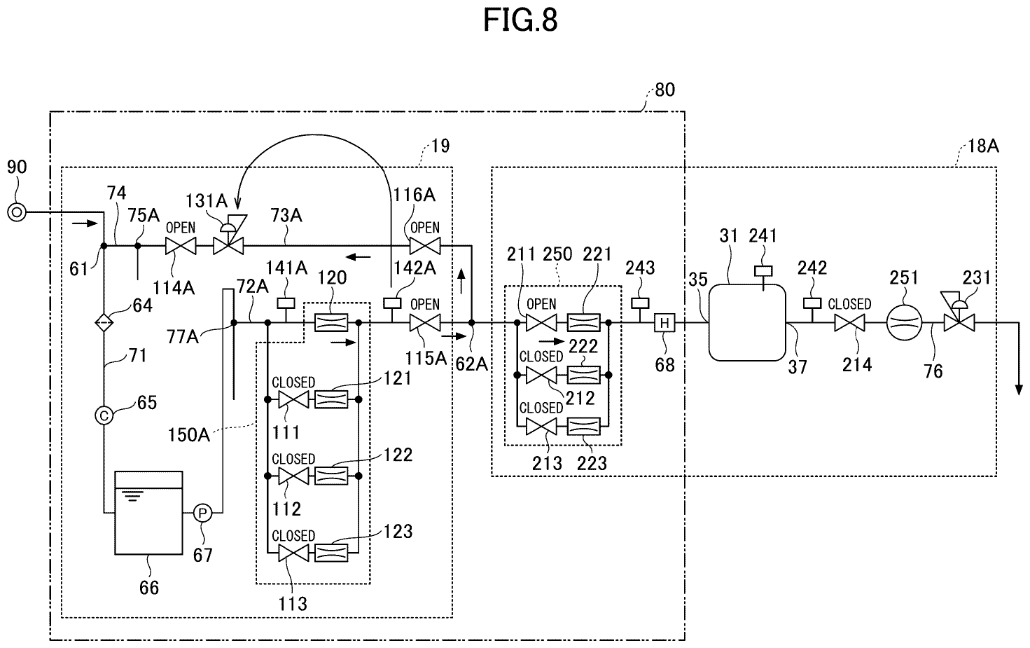

In the pressure increase at the first flow rate, as illustrated in FIG. 8, the valves 111 to 113 are closed, and the valves 114A, 115A, and 116A are opened. The processing fluid guided to the second supply line 72A reaches the branch point 62A via the single orifice 120 without passing through the three orifices 121 to 123.

A portion of the processing fluid that has reached the branch point 62A is supplied to the dry unit 18A, and the other portion of the processing fluid flows from the branch point 62A to the first branch line 73A. The processing fluid guided to the first branch line 73A reaches the connection point 61 via the valves 116A, the back pressure valve 131A, the valve 114A, and the second branch line 74, and thereafter returns to the tank 66 via the filter 64 and the condenser 65.

During this series of operations, the controller 7 receives the output from the pressure sensor 142A and adjusts the set pressure of the back pressure valve 131A so that the pressure of the processing fluid flowing through a portion on the downstream side of the orifice 120 of the second supply line 72A is at a preset pressure (e.g., 7.0 MPa). That is, the controller 7 controls the pressure of the processing fluid at the branch point 62A by changing the amount of the processing fluid flowing through the first branch line 73A.

In the dry unit 18A, the valve 211 is opened, and the valves 212, 213, and 214 are closed. Therefore, the processing fluid supplied to the dry unit 18 reaches the heater 68 via the orifice 221 without passing through the orifices 222 and 223, and is heated by the heater 68 to be in the supercritical state. Then, the processing fluid in the supercritical state is supplied to the main body 31 at the first flow rate. The pressure inside the main body 31 to which the processing fluid in the supercritical state is supplied gradually increases from the 0 MPa. In the pressure increase at the first flow rate, the pressure of the processing fluid at the branch point 62A is maintained at the preset pressure, and thus the pressure at which the processing fluid in the supercritical state is supplied into the main body 31 is constant.

During the pressure increase at the first flow rate, the controller 7 receives the output from the pressure sensor 242, and when the pressure inside the main body 31 reaches the preset pressure, the controller 7 shifts to the pressure increase at the second flow rate. The preset pressure may be 3.0 MPa or less, for example 1.0 MPa. Instead of using the pressure value as a reference, the pressure increase may be shifted to the pressure increase at the second flow rate when a preset time elapses after the start of the pressure increase at the first flow rate.

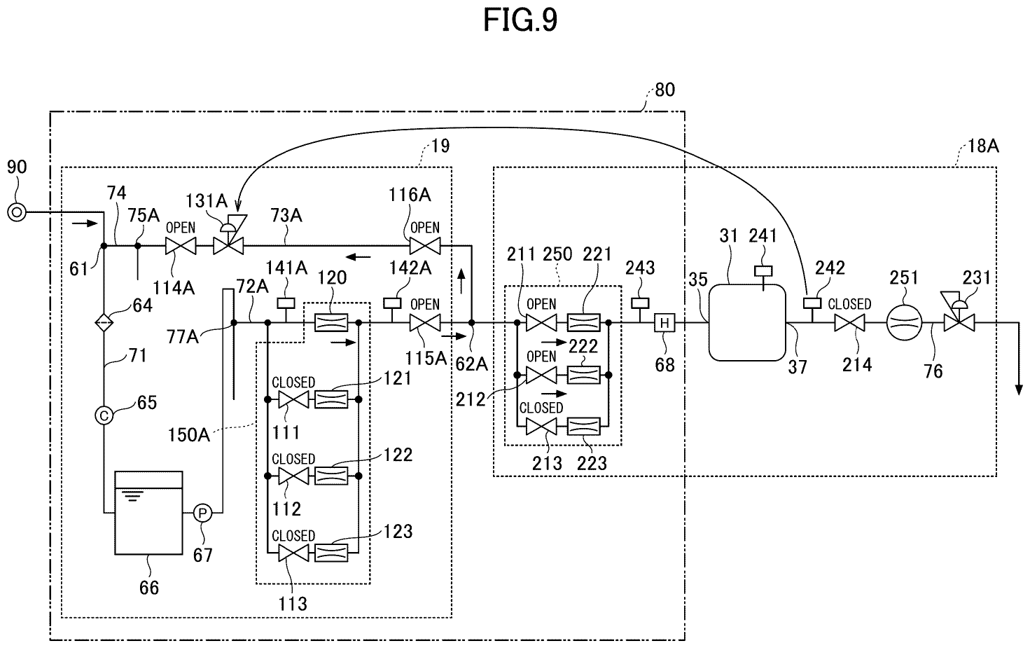

In the pressure increase at the second flow rate, first, as illustrated in FIG. 9, the valve 212 is opened. The states of the other valves are substantially the same as the states illustrated in FIG. 8. As a result, the processing fluid supplied to the dry unit 18A reaches the heater 68 via not only the orifice 221 but also the orifice 222, and is heated by the heater 68 to be in the supercritical state. Therefore, the flow rate of the processing fluid in the supercritical state supplied to the main body 31 increases to the second flow rate.

During this series of operations, the controller 7 receives the output from the pressure sensor 242 and adjusts the set pressure of the back pressure valve 131A so that the pressure inside the main body 31 gradually increases with a predetermined change. That is, the controller 7 controls the pressure of the processing fluid at the branch point 62A by changing the amount of the processing fluid flowing through the first branch line 73A. The pressure of the processing fluid at the branch point 62A gradually increases, and thus the pressure at which the processing fluid in the supercritical state is supplied into the main body 31 also gradually increases. When the pressure inside the main body 31 reaches a preset pressure, the controller 7 shifts to the pressure increase at the third flow rate. The preset pressure may be 7.0 MPa or less, for example, 7.0 MPa. Instead of using the pressure value as a reference, the pressure increase may be shifted to the pressure increase at the third flow rate when a preset time elapses from the start of the pressure increase at the second flow rate.

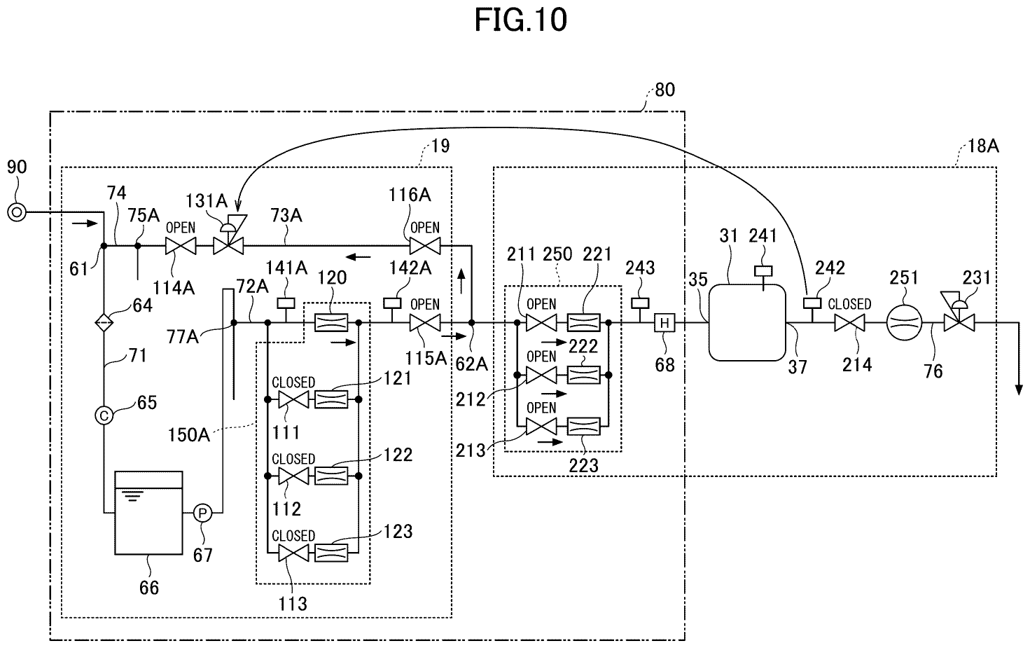

In the pressure increase at the third flow rate, first, the valve 213 is opened as illustrated in FIG. 10. The states of the other valves are substantially the same as the states illustrated in FIG. 9. As a result, the processing fluid supplied to the dry unit 18A reaches the heater 68 via the orifices 221, 222, and 223, and is heated by the heater 68 to be in the supercritical state. Therefore, the flow rate of the processing fluid in the supercritical state supplied into the main body 31 increases to the third flow rate.

During this series of operations, the controller 7 receives the output from the pressure sensor 242 and adjusts the set pressure of the back pressure valve 131A so that the pressure inside the main body 31 gradually increases with a predetermined change. That is, the controller 7 controls the pressure of the processing fluid at the branch point 62A by changing the amount of the processing fluid flowing through the first branch line 73A. The pressure of the processing fluid at the branch point 62A gradually increases, and thus the pressure at which the processing fluid in the supercritical state is supplied into the main body 31 also gradually increases.

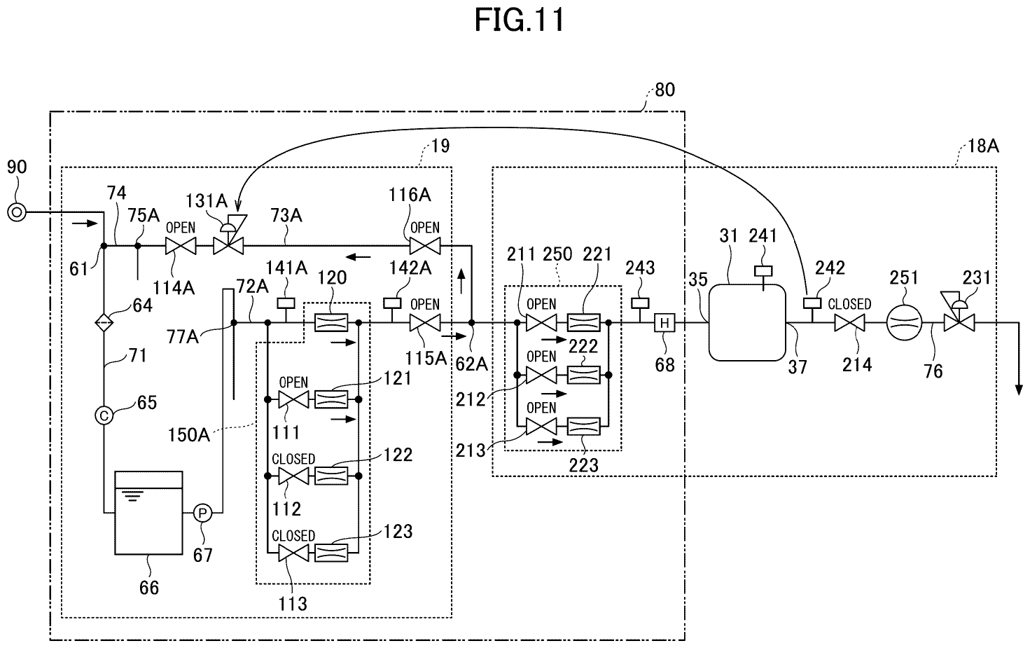

In the pressure increase at the third flow rate, as the pressure of the processing fluid at the branch point 62A increases, a differential pressure between the upstream side and the downstream side of the orifice 120 decreases. Thus, when the pressure of the processing fluid at the branch point 62A reaches a preset value (e.g., 11.0 MPa), the controller 7 opens the valve 111 as illustrated in FIG. 11. The states of the other valves are substantially the same as the states illustrated in FIG. 10. As a result, even when the differential pressure between the upstream side and the downstream side of the orifice 120 is reduced, the processing fluid can be continuously caused to flow through the first branch line 73A and the second branch line 74. During this period, the pressure inside the main body 31 increases from 7.0 MPa to 13.0 MPa, for example.

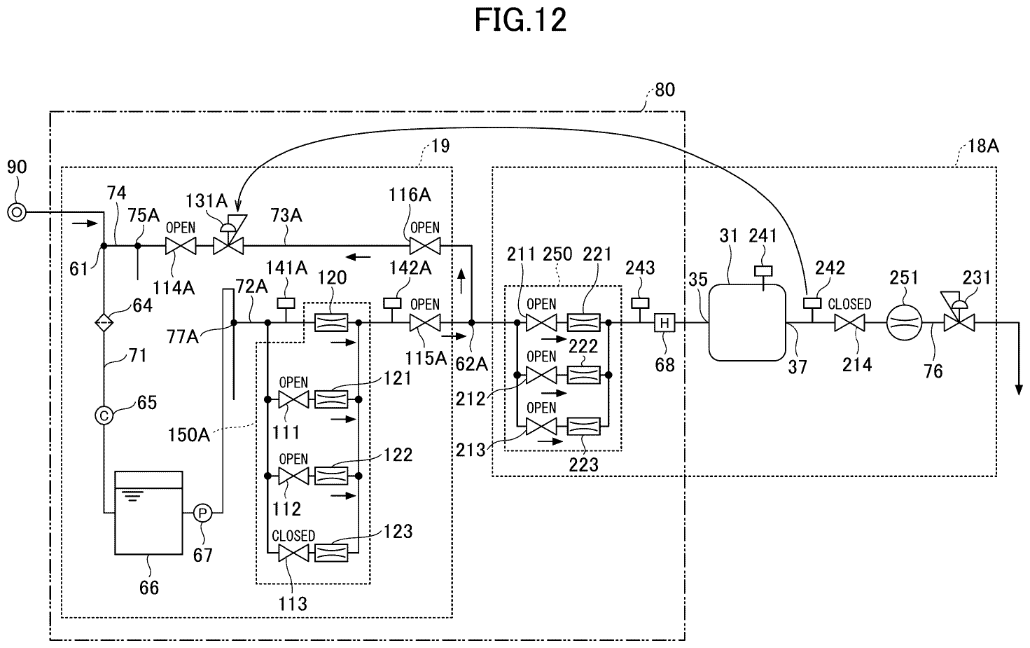

When the pressure of the processing fluid at the branch point 62A reaches a greater preset pressure (e.g., 14.5 MPa), the controller 7 also opens the valve 112 as illustrated in FIG. 12. The states of the other valves are substantially the same as the states illustrated in FIG. 11. As a result, even when the differential pressure between the upstream side and the downstream side of the orifice 120 is further reduced, the processing fluid can be continuously caused to flow through the first branch line 73A and the second branch line 74. During this period, the pressure inside the main body 31 increases, for example, from 13.0 MPa to 15.0 MPa.

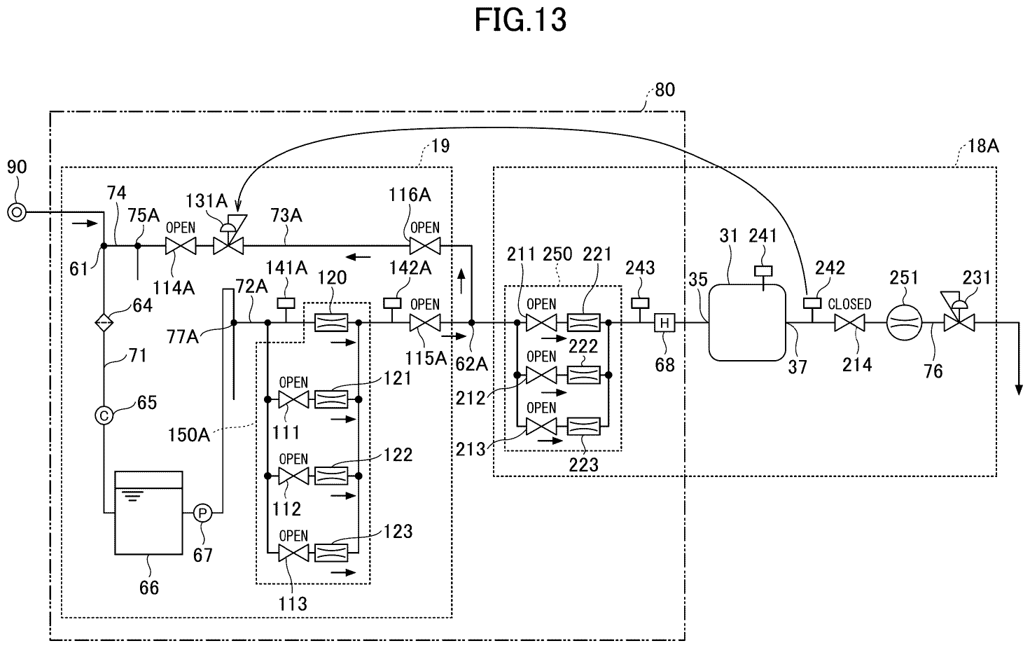

When the pressure of the processing fluid at the branch point 62A reaches a still greater predetermined pressure (e.g., 17.0 MPa), the controller 7 also opens the valve 113 as illustrated in FIG. 13. The states of the other valves are substantially the same as the states illustrated in FIG. 12. As a result, even when the differential pressure between the upstream side and the downstream side of the orifice 120 is further reduced, the processing fluid can be continuously caused to flow through the first branch line 73A and the second branch line 74. During this period, the pressure inside the main body 31 increases, for example, from 15.0 MPa to 16.0 MPa.

The pressurization process is performed as described above.

### <Circulation Process>

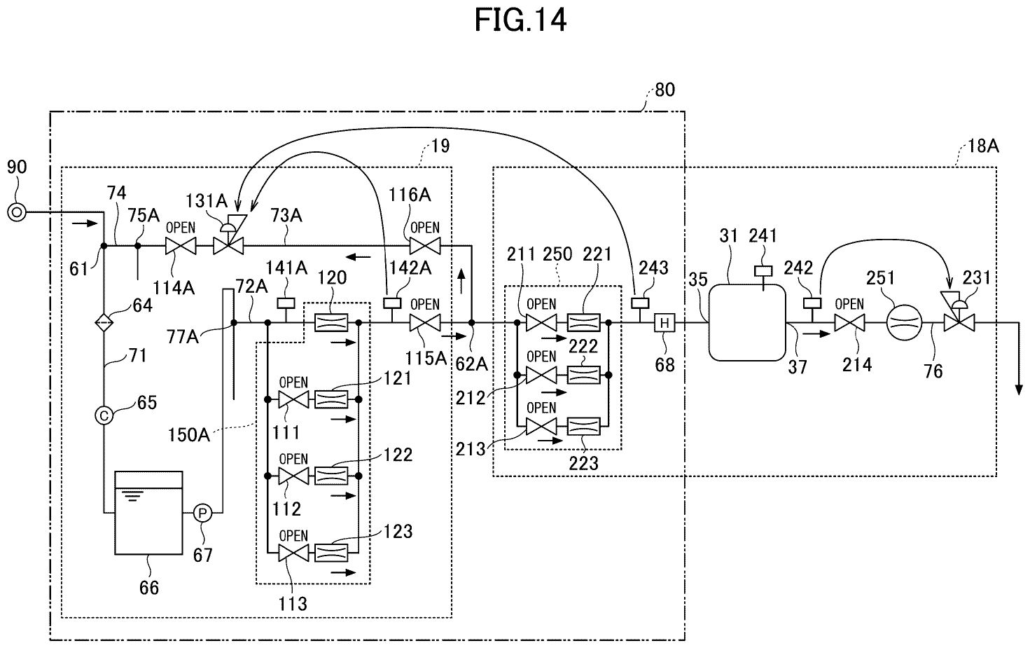

A circulation process is performed after the pressurization process. The circulation process is a process of drying the liquid film of the IPA liquid on the wafer W transferred into the main body 31 by using the processing fluid in the supercritical state. In the circulation process, as illustrated in FIG. 14, the valves 111 to 113 are opened. Additionally, the valves 114A, 115A, and 116A are opened. The processing fluid guided to the second supply line 72A reaches the branch point 62A via the four orifices 120 to 123.

A portion of the processing fluid that has reached the branch point 62A is supplied to the dry unit 18A, and the other portion of the processing fluid flows from the branch point 62A to the first branch line 73A. The processing fluid guided to the first branch line 73A reaches the connection point 61 via the valve 116A, the back pressure valve 131A, the valve 114A, and the second branch line 74, and thereafter returns to the tank 66 via the filter 64 and the condenser 65.

Additionally, in the dry unit 18A, the valves 211 to 214 are opened. Therefore, the processing fluid flows through the second supply line 72A and is supplied into the main body 31 from the supply port 35. Additionally, the processing fluid flows from the drain port 37 of the main body 31 through the drain line 76, and is drained to the outside through the valve 214, the flow meter 251, and the back pressure valve 231.

During the series of operations, first, the controller 7 receives a first pressure P1 of the processing fluid in the liquid state measured by the pressure sensor 243 and a second pressure P2 of the processing fluid in the liquid state measured by the pressure sensor 142A. Next, the controller 7 calculates the supply flow rate of the processing fluid flowing through the second supply line 72A based on the first pressure P1 and the second pressure P2. Next, the controller 7 adjusts the set pressure of the back pressure valve 131A so that the calculated supply flow rate of the processing fluid becomes the set flow rate at the time of the circulation process.

The controller 7 calculates a supply flow rate Q of the processing fluid flowing through the second supply line 72 by, for example, a calculation formula of Formula (1).

$$Q = Cd \cdot {( Δ P )}^{1 / 2} \qquad ( 1 )$$

In Formula (1), ΔP is a value obtained by subtracting the first pressure P1 from the second pressure P2 (ΔP=P2−P1), and Cd is a flow rate coefficient.

The flow rate coefficient Cd can be calculated by a calculation formula of Formula (2), for example, when the processing fluid circulates in the main body 31 under a predetermined condition and the first pressure P1, the second pressure P2, and the drain flow rate of the processing fluid measured by the flow meter 251 are stabilized.

$$Qs = Cd \cdot {( Δ Ps )}^{1 / 2} \qquad ( 2 )$$

In Formula (2), Qs is the drain flow rate of the processing fluid measured by the flow meter 251 when the first pressure P1, the second pressure P2, and the drain flow rate of the processing fluid that is measured by the flow meter 251 are stabilized. In Formula (2), ΔPs is a differential pressure (ΔPs=P1−P2) between the second pressure P2 and the first pressure P1 when the first pressure P1, the second pressure P2, and the drain flow rate of the processing fluid measured by the flow meter 251 are stabilized.

The flow rate coefficient Cd may be calculated for each of the dry units 18A to 18C. In this case, excellent evenness of the supply flow rates among the multiple dry units 18A to 18C can be obtained. The flow rate coefficient Cd may be calculated for each of the states of the valves 211 to 213. The flow rate coefficient Cd may include a flow rate coefficient in a case where one of the three valves 211 to 213 is open, a flow rate coefficient in a case where two of the three valves 211 to 213 are opened, and a flow rate coefficient in a case where all of the three valves 211 to 213 are opened.

A flow rate coefficient Cd_{A} in a case where the valve 211 is open is calculated by the calculation formula of Formula (2) in a state where the valve 211 is open, the valves 212 and 213 are closed, and the processing fluid is caused to circulate through the main body 31 under the predetermined condition. A flow rate coefficient Cd_{B} in a case where the valve 212 is open and a flow rate coefficient Cd_{C} in a case where the valve 213 is open are calculated in substantially the same manner as the flow rate coefficient Cd_{A}.

The flow rate coefficient Cd_{AB} in a case where the valves 211 and 212 are open is calculated by the calculation formula of Formula (2) in a state where the valves 211 and 212 are open, the valve 213 is closed, and the processing fluid is caused to circulate in the main body 31 under the predetermined condition. The flow rate coefficient Cd_{BC} in a case where the valves 212 and 213 are open and the flow rate coefficient Cd_{C} in a case where the valves 211 and 213 are open are calculated in substantially the same manner as the flow rate coefficient Cd_{AB}.

The flow rate coefficient Cd_{ABC} in a case where all of the valves 211 to 213 are open is calculated by the calculation formula of Formula (2) in a state where the valves 211, 212, and 213 are open and the processing fluid is caused to circulate in the main body 31 under the predetermined condition. The flow rate coefficient Cd_{ABC} in the case where all of the valves 211 to 213 are open may be calculated by the sum of the flow rate coefficient Cd_{A}, the flow rate coefficient Cd_{B}, and the flow rate coefficient Cd_{C} (Cd_{A}+Cd_{B}+Cd_{C}).

In the circulation process, the controller 7 receives the output from the pressure sensor 242 and adjusts the set pressure of the back pressure valve 231 so that the pressure inside the main body 31 is maintained at the set pressure in the circulation process.

### <Drain Process>

A drain process is performed after the circulation process. The drain process is a process of draining the processing fluid from the main body 31. In the drain process, the valves 211, 212, and 213 are closed. The states of the other valves are substantially the same as the states illustrated in FIG. 14. When the pressure inside the main body 31 becomes lower than the critical pressure of the processing fluid by the drain process, the processing fluid in the supercritical state is vaporized and separated from the inside of the recess of the pattern. With this, the drying process for one wafer W is completed.

When the processing fluid is supplied to the dry units 18B and 18C, the valves 111 to 113, 211 to 213, and the like are controlled in substantially the same manner as the valves are controlled when the processing fluid is supplied to the dry unit 18A.

As described above, in the substrate processing apparatus 1, in the circulation process, first, the controller 7 calculates the supply flow rate of the processing fluid flowing through the second supply line 72A based on the first pressure P1 measured by the pressure sensor 243 and the second pressure P2 measured by the pressure sensor 142A. Next, the controller 7 adjusts the set pressure of the back pressure valve 231 so that the calculated supply flow rate of the processing fluid becomes the set flow rate during the circulation process. In this case, the back pressure valve 231 can be controlled based on the supply flow rate of the processing fluid in the liquid state flowing on the upstream side of the main body 31, and thus the responsiveness of the flow rate control of the supercritical fluid can be improved. As a result, excellent evenness of the supply flow rate among the multiple dry units 18A to 18C can be obtained. Additionally, excellent evenness of the supply flow rate among multiple processes performed in the specific dry units 18A to 18C can be obtained. Additionally, the flow meter for controlling the back pressure valve 231 is not required to be provided on the upstream side of the main body 31.

With respect to the above, a case where the set pressure of the back pressure valve 131A is adjusted so that the pressure measured by the pressure sensor 242 provided in the drain line 76 is maintained at the set pressure during the circulation process will be considered. The pressure sensor 242 measures the pressure of the processing fluid on the downstream side of the main body 31. The processing fluid on the downstream side of the main body 31 is in the supercritical state or a gas state and is compressible. Additionally, the pressure sensor 242 is provided at a position farther from the back pressure valve 131A than the pressure sensors 243 and 142A are provided. Therefore, when the back pressure valve 131A is controlled based on the pressure measured by the pressure sensor 242, it is difficult to improve the responsiveness of the flow rate control of the supercritical fluid.

Additionally, in the substrate processing apparatus 1, the pressure sensors 243 and 142A are provided on the upstream side of the heater 68. Therefore, the supply flow rate of the processing fluid in the liquid state can be reliably measured. As a result, the supply flow rate of the processing fluid into the main body 31 can be adjusted with high accuracy.

Additionally, in the substrate processing apparatus 1, the orifices 221 to 223 are provided at positions where the processing fluid in the liquid state flows. The density and viscosity of the processing fluid in the liquid state hardly change due to a temperature change or a pressure change, and thus the flow rate coefficient Cd is easily calculated. In contrast, the density and viscosity of the processing fluid in the supercritical state change due to a temperature change or a pressure change, it is difficult to calculate the flow rate coefficient Cd.

Additionally, in the substrate processing apparatus 1, in the wait process, the pressurization process, the circulation process, and the drain process, the processing fluid can be constantly caused to circulate through the flow path passing through the first supply line 71, the second supply lines 72A to 72C, the first branch lines 73A to 73C, and the second branch line 74. Therefore, the difference in the temperature of the processing fluid supplied into the main body 31 between the processes in the pressurization process, the circulation process, and the drain process can be reduced.

Additionally, in the substrate processing apparatus 1, the flow rate of the processing fluid in the supercritical state supplied into the main body 31 during the pressurization process can be adjusted. For example, the processing fluid may be supplied at the first flow rate, which is small, then the processing fluid may be supplied at the second flow rate, which is greater, and then the processing fluid may be supplied at the third flow rate, which is still greater. A fine pattern may be formed on the surface of the wafer W carried into the main body 31. In this case, when the processing fluid is supplied at a great flow rate, the pattern may collapse. With respect to the above, by performing the supply at the first flow rate before the supply at the second flow rate, the processing fluid in the supercritical state is spread in the pattern while suppressing the collapse of the pattern, and the collapse of the pattern can be suppressed even when the processing fluid is supplied at the second flow rate and the third flow rate. Further, the processing fluid can be supplied at the second flow rate and the third flow rate greater than the first flow rate, and thus the time required for increasing the pressure can be reduced by supplying the processing fluid at the second flow rate and the third flow rate after the processing fluid in the supercritical state spreads in the pattern.

Additionally, in the substrate processing apparatus 1, the heater 68 is provided on the downstream side (the main body 31 side) of the first flow rate adjuster 250. Therefore, the temperature of the processing fluid in the supercritical state when supplied into the main body 31 is easily stabilized. In particular, excellent temperature evenness among the multiple dry units 18A to 18C can be obtained.

Additionally, the third flow rate adjusters 150A to 150C are provided in the supply unit 19, and thus the flow rate (the circulation flow rate) of the processing fluid circulating through the first branch lines 73A to 73C can be stabilized. For example, in the pressurization at the first flow rate, the pressure inside the main body 31 is caused to be low and the pressure of the processing fluid at the branch point 62A is also caused to be low, and thus the differential pressure between the upstream side and the downstream side of the orifice 120 increases. Even in this case, in the present embodiment, by closing the valves 111 to 113, the circulation flow rate can be reduced, thereby suppressing the load of the pump 67. Additionally, in the pressurization at the second flow rate, the valves 111 to 113 are appropriately opened in accordance with the differential pressure between the upstream side and the downstream side of the orifice 120, and thus the processing fluid can continuously flow through the first branch line 73A and the second branch line 74.

The embodiments disclosed herein are to be considered in all respects as illustrative and not restrictive. The above-described embodiments may be omitted, replaced, and modified in various forms without departing from the scope and spirit of the appended claims.

For example, in the pressurization process, when the first pressure P1 and the second pressure P2 are greater than or equal to a predetermined pressure, the controller 7 may adjust the back pressure valve 231 based on the first pressure P1 and the second pressure P2, as in the circulation process. For example, when the process fluid is CO₂, the predetermined pressure may be 6.0 MPa. In this case, the processing fluid in the second supply line 72A located upstream of the heater 68 is in the liquid state, and thus the flow rate coefficient Cd is easily calculated. The predetermined pressure may be a critical pressure of the processing fluid.

For example, the processing fluid used in the drying process may be a fluid other than CO₂ (e.g., a fluorine-based fluid), and any fluid that can remove the liquid for dry prevention filled on the wafer W in the supercritical state may be used as the processing fluid. Additionally, the liquid for dry prevention is not limited to the IPA, and any liquid that can be used as the liquid for dry prevention can be used. The substrate to be processed is not limited to the wafer W described above, and may be another substrate such as a glass substrate for an LCD, a ceramic substrate, or the like.

What is claimed is:

1. A substrate processing apparatus comprising:
a processing container having a processing space configured to accommodate a substrate having a surface wetted with a liquid; and
a processing fluid supply configured to supply a processing fluid in a supercritical state into the processing container;
wherein the processing fluid supply includes:
a fluid supply line having one end connected to a fluid supply source and another end connected to the processing container;
a pump provided in the fluid supply line;
a heater provided in the fluid supply line at a location on a downstream side of the pump, the heater being configured to heat the processing fluid to generate the processing fluid in the supercritical state;
a first flow rate adjuster provided in the fluid supply line at a location between the pump and the heater, the first flow rate adjuster being configured to adjust a supply flow rate of the processing fluid supplied into the processing container;
a first pressure measurement section provided in the fluid supply line at a location between the first flow rate adjuster and the heater, the first pressure measurement section being configured to measure a pressure of the processing fluid;
a second pressure measurement section provided in the fluid supply line at a location between the pump and the first flow rate adjuster, the second pressure measurement section being configured to measure a pressure of the processing fluid;
a branch point provided between the pump and the first flow rate adjuster in the fluid supply line;
a connection point provided on an upstream side of the pump in the fluid supply line;
a branch line connecting the branch point to the connection point;
a second flow rate adjuster provided in the branch line and configured to adjust the supply flow rate of the processing fluid supplied into the processing container; and
a controller configured to control the second flow rate adjuster based on a first pressure of the processing fluid in a liquid state measured by the first pressure measurement section and a second pressure of the processing fluid in the liquid state measured by the second pressure measurement section.

2. The substrate processing apparatus as claimed in claim 1,
wherein the processing fluid is carbon dioxide, and
wherein the controller controls the second flow rate adjuster based on the first pressure and the second pressure in response to determining that the first pressure and the second pressure are 6.0 MPa or greater.

3. The substrate processing apparatus as claimed in claim 1, wherein the first flow rate adjuster includes:
a first open/close valve provided in the fluid supply line; and
a first throttle connected in series with the first open/close valve.

4. The substrate processing apparatus as claimed in claim 1, further comprising a drain section configured to drain the processing fluid from the processing container,
wherein the drain section includes:
a drain line connected to the processing container; and
a flow meter provided in the drain line and configured to measure a drain flow rate of the processing fluid drained from the processing container,
wherein the controller calculates, based on a differential pressure between the second pressure and the first pressure and based on the drain flow rate, a coefficient of a calculation formula representing a relationship between the supply flow rate and the differential pressure.

5. The substrate processing apparatus as claimed in claim 4,
wherein the controller performs:
(a) heating the processing fluid and waiting before supplying the processing fluid into the processing container;
(b) increasing a pressure inside the processing container to a processing pressure by supplying the processing fluid into the processing container;
(c) supplying the processing fluid into the processing container and draining the processing fluid inside the processing container from the drain section; and
(d) stopping the supply of the processing fluid into the processing container and draining the processing fluid inside the processing container from the drain section, and
wherein the controller controls the second flow rate adjuster based on the first pressure and the second pressure in (c).

6. The substrate processing apparatus as claimed in claim 5,
wherein the drain section includes:
a third pressure measurement section provided in the drain line and configured to measure the pressure inside the processing container; and
a pressure adjuster provided in the drain line and configured to adjust the pressure inside the processing container, and
wherein the controller controls the pressure adjuster based on the pressure inside the processing container measured by the third pressure measurement section in (c).

7. The substrate processing apparatus as claimed in claim 6,
wherein (b) includes:
(b1) increasing the pressure inside the process container to a critical pressure of the processing fluid; and
(b2) increasing the pressure inside the process container from the critical pressure of the processing fluid to the processing pressure, and
wherein the controller controls the second flow rate adjuster based on the first pressure and the second pressure in (b2).

8. The substrate processing apparatus as claimed in claim 1,
wherein the processing fluid supply includes a cooler provided in the fluid supply line and configured to cool the processing fluid in a gas state to generate the processing fluid in the liquid state, and
wherein the pump is provided in the fluid supply line on a downstream side of the cooler.

9. A fluid supply system for supplying a processing fluid in a supercritical state into a processing container having a processing space configured to accommodate a substrate having a surface wetted with a liquid, the fluid supply system comprising:
a fluid supply line having one end connected to a fluid supply source and another end connected to the processing container;
a pump provided in the fluid supply line;
a heater provided in the fluid supply line at a location on a downstream side of the pump, the heater being configured to heat the processing fluid to generate the processing fluid in the supercritical state;
a first flow rate adjuster provided in the fluid supply line at a location between the pump and the heater, the first flow rate adjuster being configured to adjust a supply flow rate of the processing fluid supplied into the processing container;
a first pressure measurement section provided in the fluid supply line at a location between the first flow rate adjuster and the heater, the first pressure measurement section being configured to measure a pressure of the processing fluid;
a second pressure measurement section provided in the fluid supply line at a location between the pump and the first flow rate adjuster, the second pressure measurement section being configured to measure a pressure of the processing fluid;
a branch point provided between the pump and the first flow rate adjuster in the fluid supply line;
a connection point provided on an upstream side of the pump in the fluid supply line;
a branch line connecting the branch point to the connection point;
a second flow rate adjuster provided in the branch line and configured to adjust the supply flow rate of the processing fluid supplied into the processing container; and
a controller configured to control the second flow rate adjuster based on a first pressure of the processing fluid in a liquid state measured by the first pressure measurement section and a second pressure of the processing fluid in the liquid state measured by the second pressure measurement section.

10. The fluid supply system as claimed in claim 9, wherein
wherein the processing fluid is carbon dioxide, and
wherein the controller controls the second flow rate adjuster based on the first pressure and the second pressure in response to determining that the first pressure and the second pressure are 6.0 MPa or greater.

11. The fluid supply system as claimed in claim 9, wherein the first flow rate adjuster includes:
a first open/close valve provided in the fluid supply line; and
a first throttle connected in series with the first open/close valve.

12. The fluid supply system as claimed in claim 9, further comprising a cooler provided in the fluid supply line and configured to cool the processing fluid in a gas state to generate the processing fluid in the liquid state,
wherein the pump is provided in the fluid supply line on a downstream side of the cooler.

13. A substrate processing method using a substrate processing apparatus including:
a processing container having a processing space configured to accommodate a substrate having a surface wetted with a liquid; and
a processing fluid supply configured to supply a processing fluid in a supercritical state into the processing container,
wherein the processing fluid supply includes:
a fluid supply line having one end connected to a fluid supply source and another end connected to the processing container;
a pump provided in the fluid supply line;
a heater provided in the fluid supply line at a location on a downstream side of the pump, the heater being configured to heat the processing fluid to generate the processing fluid in the supercritical state;
a first flow rate adjuster provided in the fluid supply line at a location between the pump and the heater, the first flow rate adjuster being configured to adjust a supply flow rate of the processing fluid supplied into the processing container;
a first pressure measurement section provided in the fluid supply line at a location between the first flow rate adjuster and the heater, the first pressure measurement section being configured to measure a pressure of the processing fluid;
a second pressure measurement section provided in the fluid supply line at a location between the pump and the first flow rate adjuster, the second pressure measurement section being configured to measure a pressure of the processing fluid;
a branch point provided between the pump and the first flow rate adjuster in the fluid supply line;
a connection point provided on an upstream side of the pump in the fluid supply line;
a branch line connecting the branch point to the connection point; and
a second flow rate adjuster provided in the branch line and configured to adjust the supply flow rate of the processing fluid supplied into the processing container,
the substrate processing method comprising controlling the second flow rate adjuster based on a first pressure of the processing fluid in a liquid state measured by the first pressure measurement section and a second pressure of the processing fluid in the liquid state measured by the second pressure measurement section.

14. The substrate processing method as claimed in claim 13,
wherein the processing fluid is carbon dioxide, and
wherein the second flow rate adjuster is controlled based on the first pressure and the second pressure in response to determining that the first pressure and the second pressure are 6.0 MPa or greater.

15. The substrate processing method as claimed in claim 13, wherein the first flow rate adjuster includes:
a first open/close valve provided in the fluid supply line; and
a first throttle connected in series with the first open/close valve.

16. The substrate processing method as claimed in claim 13,
wherein the substrate processing apparatus further comprises a drain section configured to drain the processing fluid from the processing container,
wherein the drain section includes:
a drain line connected to the processing container; and
a flow meter provided in the drain line and configured to measure a drain flow rate of the processing fluid drained from the processing container, and
wherein the controlling of the second flow rate adjuster further includes calculating, based on a differential pressure between the second pressure and the first pressure and based on the drain flow rate, a coefficient of a calculation formula representing a relationship between the supply flow rate and the differential pressure.

17. The substrate processing method as claimed in claim 16,
wherein the substrate processing method comprises:
(a) heating the processing fluid and waiting before supplying the processing fluid into the processing container;
(b) increasing a pressure inside the processing container to a processing pressure by supplying the processing fluid into the processing container;
(c) supplying the processing fluid into the processing container and draining the processing fluid inside the processing container from the drain section; and
(d) stopping the supply of the processing fluid into the processing container and draining the processing fluid inside the processing container from the drain section, and
wherein the second flow rate adjuster is controlled based on the first pressure and the second pressure in (c).

18. The substrate processing method as claimed in claim 17,
wherein the drain section includes:
a third pressure measurement section provided in the drain line and configured to measure the pressure inside the processing container; and
a pressure adjuster provided in the drain line and configured to adjust the pressure inside the processing container, and
wherein the pressure adjuster is controlled based on the pressure inside the processing container measured by the third pressure measurement section in (c).

19. The substrate processing method as claimed in claim 18,
wherein (b) includes:
(b1) increasing the pressure inside the process container to a critical pressure of the processing fluid; and
(b2) increasing the pressure inside the process container from the critical pressure to the processing pressure of the processing fluid, and
wherein the second flow rate adjuster is controlled based on the first pressure and the second pressure in (b2).

20. The substrate processing method as claimed in claim 13,
wherein the processing fluid supply includes a cooler provided in the fluid supply line and configured to cool the processing fluid in a gas state to generate the processing fluid in the liquid state, and
wherein the pump is provided on a downstream side of the cooler.
